(19) United States
(12) Patent Application Publication
(10) Pub. No.: US 2005/0174869 A1
(43) Pub. Date: Aug. 11, 2005

(54) System and method for data storage and tracking

(76) Inventors: Rajiv Kottomtharayil, Ocean, NJ (US); Yu Wang, Edison, NJ (US); Parag Gokhale, Ocean, NJ (US)

Correspondence Address: BROWN, RAYSMAN, MILLSTEIN, FELDER & STEINER LLP, 900 THIRD AVENUE, NEW YORK, NY, 10022, US

(21) Appl. No.: 10/990,363

(22) Filed: Nov. 15, 2004

Related U.S. Application Data
(60) Provisional application No. 60/519,525, filed on Nov. 13, 2003.

(51) Int. Cl. G11C 7/00

(52) U.S. Cl. 365/222

(57) ABSTRACT

The invention provides a method and system for transferring storage media scheduled for export from a storage device. The storage media is identified according to retention characteristics for export, and placed in a location near to the storage device exit point prior to it scheduled export out of the storage device to offsite storage. The storage device interfaces with the storage management system used at the offsite storage to provide tracking of the storage media at the offsite location. The location of the media is tracked within the storage system and at the offsite storage, for administrative, reporting or other uses.

### PRIORITY APPLICATIONS

This application claims the benefit of U.S. provisional application No. 60/519,525 titled SYSTEM AND METHOD FOR DATA STORAGE AND TRACKING, filed Nov. 13, 2003, which application is incorporated herein by reference in its entirety.

### RELATED APPLICATIONS

This application is related to the following pending applications, each of which is hereby incorporated herein by reference in its entirety:
U.S. Provisional Patent Application Ser. No. 60/460,234, titled SYSTEM AND METHOD FOR PERFORMING STORAGE OPERATIONS IN A COMPUTER NETWORK, filed Apr. 3, 2003, attorney docket number 4982/35PROV;
application Ser. No. 10/818,749, titled SYSTEM AND METHOD FOR DYNAMICALLY PERFORMING STORAGE OPERATIONS IN A COMPUTER NETWORK, filed Apr. 5, 2004, attorney docket number 4982/35; and
application Ser. No. 10/260,209, titled SYSTEM AND METHOD FOR ARCHIVING OBJECTS IN AN INFORMATION STORE, filed Sep. 30, 2002, attorney docket number 4982/19.

### COPYRIGHT NOTICE

A portion of the disclosure of this patent document contains material which is subject to copyright protection. The copyright owner has no objection to the facsimile reproduction by anyone of the patent document or the patent disclosures, as it appears in the Patent and Trademark Office patent files or records, but otherwise reserves all copyright rights whatsoever.

### BACKGROUND OF THE INVENTION

The invention disclosed herein relates generally to data storage systems in computer networks and, more particularly, to improvements in storing and tracking electronic data.

Storage architecture used by individual computers or data stores to store electronic data typically includes volatile storage media such as Random Access Memory RAM, and one or more nonvolatile storage devices such as hard drives, tape drives, optical disks, and other storage devices that form a part of or are directly associated with an individual computer. A network of computers such as a Local Area Network LAN or a Wide Area Network WAN, typically store electronic data via servers or stand-alone storage devices accessible via the network. Stand-alone storage devices are generally connected to one individual computer or a network of computers. Examples of network storage devices include networkable tape drives, optical libraries, Redundant Arrays of Inexpensive Disks RAID, CD-ROM jukeboxes, and other devices. Network storage devices commonly known in the art typically include physical drives in which tapes or other storage media are stored and a robotic arm which is used to place the tapes or storage media into the drives.

The tapes or other storage media are used, for example, to store or back up electronic data. The tapes or other storage media may be stored locally, for example to a system device or facility or to an offsite location. For example, third party vendors providing offsite data storage facilities, such as Iron Mountain, Inc. of Boston, Mass., store data for back up archiving or disaster recovery purposes. Typically, storage of the storage media to a local device or offsite location is provided by transferring the storage media between system devices or between system devices and the offsite location, according to a storage policy, or as necessary.

Storage media transfers are typically accomplished using a robotic arm. The robotic arm generally obtains storage media from a drive and transfers the storage media out of the network storage device, at the time the storage media is required. Since existing network storage devices can contain hundreds or even thousands of storage media and drives, transferring each individual storage media from the network storage device requires significant use of the robotic arm. Additionally, since robotic arms are typically programmed to obtain storage media in the order in which the robotic arm is directed to obtain the storage media, each storage media is often obtained without reference to the prior or subsequent storage media obtained by the robotic arm. For example, the robotic arm obtains each storage media without regard to the relative time period each storage media is required, or the relative distances between each storage media and the exit or final destination, each storage media and the prior or subsequent storage media obtained by the robotic arm, or the storage media and the robotic arm. This results in inefficiencies in performing storage operations.

Some existing storage systems have the capability to track storage media within a local or networked storage device, for example, the physical location, identification, or content of storage media within a storage device. When the storage media is transferred out of the storage device, for example, to a remote or offsite storage location, existing storage systems cannot track the location of storage media outside of the storage system, such as at the offsite storage location. Offsite storage facilities typically track items stored within the facility using tracking systems known in the art or other proprietary systems. In general, these tracking systems provide the offsite storage facility with location information for the storage media, and the location of the storage media within the offsite storage facility, but do not provide or track information specific to the storage media, such as content or data stored on the storage media. There is no single reference point to obtain tracking information, thus searching the storage system for specific storage media typically requires contacting the offsite storage facility to locate storage media. This results in inefficiencies caused by delays in locating and obtaining storage media stored at offsite storage facilities.

There is thus a need for a method and system which addresses a need to improve transfers of storage media into and out of storage devices, tracking the location of the storage media and related storage issues.

### BRIEF SUMMARY OF THE INVENTION

The present invention addresses the problems discussed above, and includes a method for facilitating transfers of storage media for export to an offsite storage facility and tracking the location of the storage media at the offsite storage facility. A method and system for optimizing transfers of storage media scheduled for export from a storage device is provided in which the storage media is identified according to retention characteristics for export, and placed in a location near to the storage device exit point prior to export out of the storage device to offsite storage. The storage device interfaces with the storage management system used at the offsite storage to provide tracking and reporting of the storage media at the offsite location.

The method involves identifying storage media scheduled for export of a storage device, and moving the storage media from a first location to a second location. The storage media is identified by the system, for example, by the storage manager, media agent, or other software module capable of managing storage media and storage operations, according to retention characteristics. Retention characteristics include for example, tracking or storage policies associated with the media, storage preferences or other parameters. The storage media is moved from a first location to a second location. Typically the first location is the storage device slot in which the storage media is stored. The second location is a location within the storage device that is closer to the storage device exit than the first location. The second location is preferably a virtual mailslot. The system, storage manager, media agent or other module capable of tracking the media, tracks the location of the media, and updates the system index with the tracking information. The system index is preferably a cache. The storage media is exported from the second location through the storage device exit for transfer to an offsite storage facility.

In preferred embodiments, the storage system communicates with the offsite storage facility. For example, the storage manager communicates directly with the storage manager of the offsite storage facility to obtain specific tracking information for the media stored at the offsite location. The communication between the storage system and offsite storage facility is preferably provided using interfacing, exposed API or other technique for communicating between storage systems.

### BRIEF DESCRIPTION OF THE DRAWINGS

The invention is illustrated in the figures of the accompanying drawings which are meant to be exemplary and not limiting, in which like references are intended to refer to like or corresponding parts, and in which:

FIG. 1 is block diagram showing a high-level view of the storage network architecture and components of one possible embodiment of the invention;

FIG. 2 is a block diagram showing a storage device known in the art;

FIG. 3 is a block diagram showing a storage device according to one possible embodiment of the invention;

FIG. 4 is a flow diagram of one possible embodiment of the invention;

FIG. 5 is a flow diagram for identifying media, a step of the flow diagram of FIG. 4, according to one possible embodiment of the invention;

FIG. 6 is a flow diagram for moving media, a step of the flow diagram of FIG. 4, according to one possible embodiment of the invention;

FIG. 7 is a flow diagram for exporting media, a step of the flow diagram of FIG. 4, according to one possible embodiment of the invention;

FIG. 8 is flow schematic showing a high-level view of the storage network architecture and components of one possible embodiment of the invention;

FIG. 9 is a flow diagram for restoring media according to one possible embodiment of the invention; and

FIG. 10 is a screenshot of a view of one possible embodiment of the invention.

### DETAILED DESCRIPTION

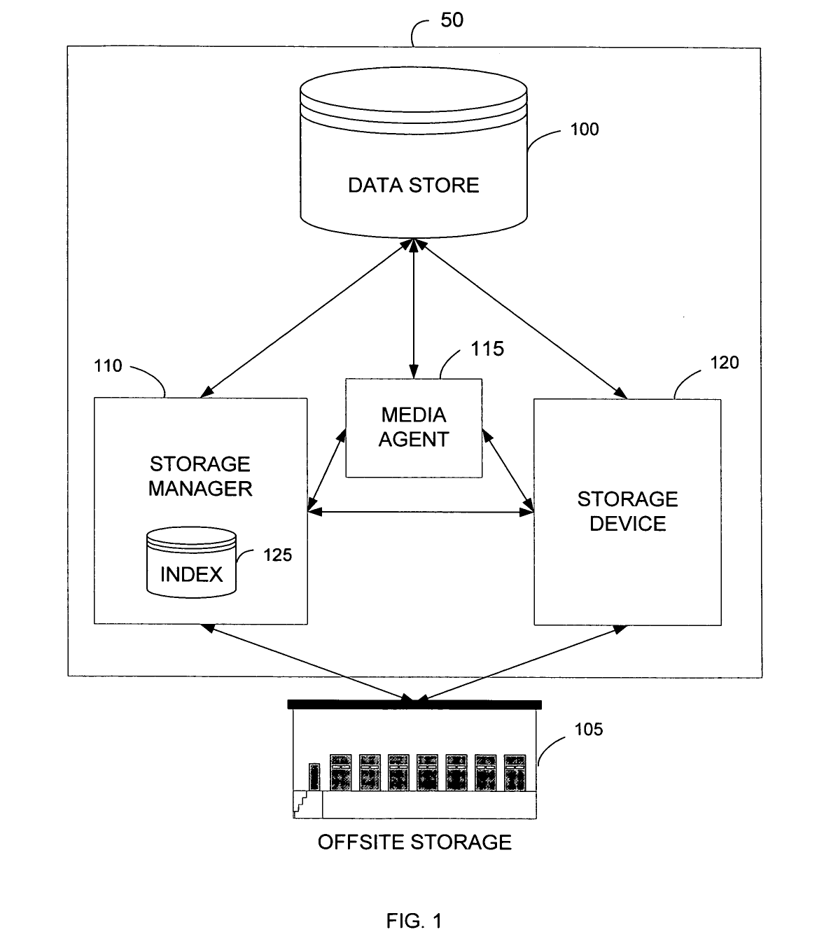

With reference to FIGS. 1 through 10, embodiments of the invention are presented. The system and components of the system as presented in FIG. 1 are exemplary of a modular storage system such as the Comm Vault Galaxy™ backup and retrieval system and QiNetix™ storage system, available from CommVault Systems, Inc. of Oceanport, N.J., and further described in U.S. Provisional Patent Application Ser. No. 60/460,234, titled SYSTEM AND METHOD FOR PERFORMING STORAGE OPERATIONS IN A COMPUTER NETWORK, filed Apr. 3, 2003, which is incorporated herein by reference in its entirety.

FIG. 1 shows a view of the storage network architecture for a system to perform storage operations on electronic data in a computer network according to an embodiment of the invention. The system includes a storage system 50 and offsite storage 105, such as a warehouse, storage facility or other facility for storing media or other data, such as the storage facilities provided by Iron Mountain, Inc. of Boston, Mass.

The storage system 50 includes a data store 100, storage manager 110, media agent 115 (or media management component), storage device 120, index 125, and other storage system components. The data store 100 contains data generated by a typical enterprise machine. For example, a data store 100 may contain Oracle data for a database, or mail server data. In the event that a data store 100 loses data, or needs to refer to data copied to storage media that is otherwise inaccessible, the data store 100 obtains the data from the storage media. The data store 100 is generally in communication with the storage manager 110, and storage device 120, and the media agent 115.

The storage manager 110 is generally a software module or application capable of directing and controlling a storage system, e.g. the storage manager 110 directs media restores to data store 100. The storage manager 110 communicates with all components of the storage 20 system, including data store 100, media agent 115, and storage device 125 to initiate, perform and manage system archives, migrations, recoveries, restores and other storage-related operations. In preferred embodiments, the storage manager 110 directs the media agent 115 to coordinate and control storage operations. Additionally, in preferred embodiments, the storage manager 110 also contains an index 125 for storing index data related to storage operations, ftuther described herein.

The media agent 115 is generally a software module that conducts data, as directed by the storage manager 110, between one or more storage devices 120, such as a tape library, a magnetic media storage device, an optical media storage device, or other storage device. For example, the media agent 115 might instruct the storage device 120 to use a robotic arm or other means to load or eject a media cartridge, and to archive, migrate, or restore application specific data. In some embodiments, the media agent 115 uses a media agent index, such as the media agent index described in U.S. Provisional Patent Application Ser. No. 60/460,234, to store index data related to storage operations. The media agent 115 generally communicates with the storage device 120 via a local bus such as a SCSI adaptor. In some embodiments, the storage device 120 is communicatively coupled to the media agent 115 via a Storage Area Network “SAN”.

The index 125 included in the storage manager 110 is generally any storage index that is maintained to store index data for each system storage backup operation, such as, the data the system generates during backup, migration, restore, and other storage operations as further described herein. The index 125 is generally a storage index known in the art, or other storage index, such as, the index cache of CommVault's Galaxy™ as further described in U.S. patent application Ser. No. 10/260,209 which is incorporated herein by reference in its entirety. The index 125 stores data related to the storage system components, including information related to each storage media item 140, such as content, location, e.g. slot 145, identifiers, storage policy, tracking policy or other characteristics and information. Index data is useful because, among other benefits, it provides the system with an efficient mechanism for locating information associated with performing storage operations, such as user files for recovery operations.

A storage policy is generally a data structure or other information which includes a set of preferences and other storage criteria for performing a storage operation. The preferences and storage criteria may include, but are not limited to: a storage location, relationships between system components, network pathway to utilize, retention policies, data characteristics, compression or encryption requirements, preferred system components to utilize in a storage operation, and other criteria relating to a storage operation. A storage policy may be stored to a storage manager index, to archive media as metadata for use in restore operations or other storage operations, or to other locations or components of the system.

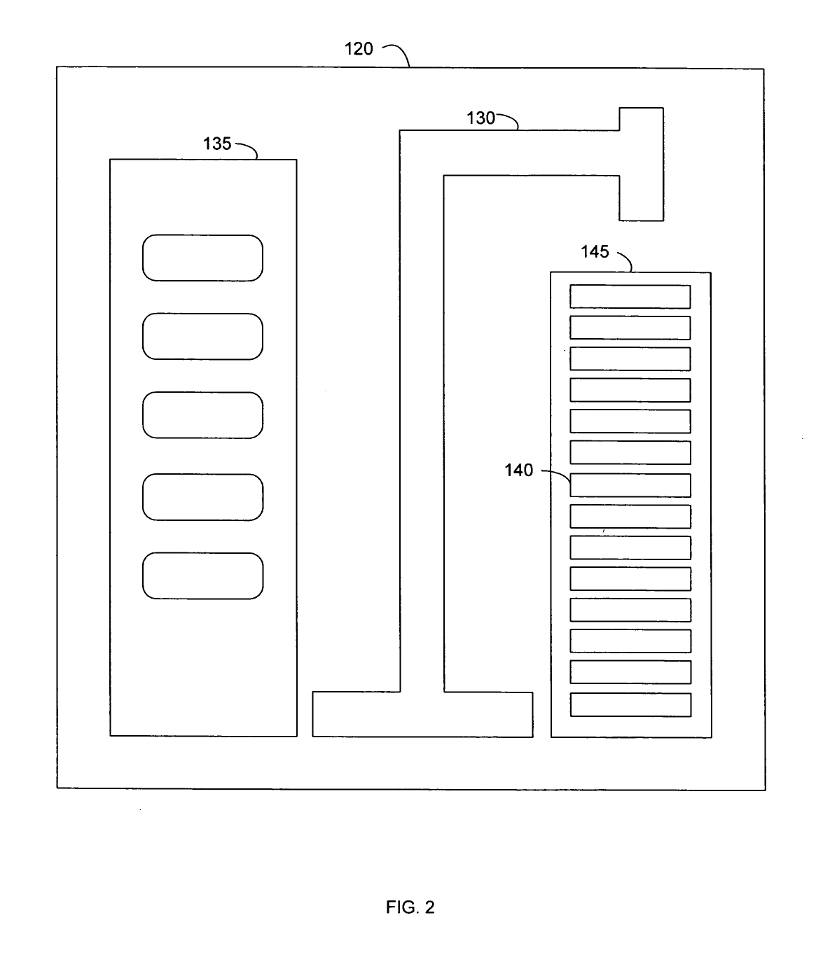

The storage device 120 is generally one or more devices suitable for the purposes further described herein. For example, the storage device 120 is generally a storage device capable of performing a storage operation. The storage device 120 typically contains the components as shown in FIG. 2, which depicts a storage device known in the art, and includes robotic arm 130, media drives 135, media 140, and slots 145. The robotic arm 130 is generally any arm capable of obtaining the media 140 and loading it into a drive 135 and correspondingly capable of removing ejected media 140 from the drive 135 and replacing the media 140 in a location in the storage device 120, such as a slot 145. The media drives 135 are generally tape drives or other drives, capable of receiving media 140 and reading the stored data on media 140. The media 140 is generally tapes, media cartridges, CD-ROMs or other media capable of storing data. The slots 145 may be one or more slots, mail slots or other storage space for media 140. A robotic arm 130 moves media 140 and places it into a slot 145. In general, media 140 is moved into and out of slots 145 as necessary to perform storage operations, or in accordance with storage policies or storage preferences. In existing storage systems, there is typically no logic used to select the slot in which to place storage media.

A storage preference is a storage policy, user preference or other storage preference. In some embodiments the storage preference is defined by a system user or system administrator. In other embodiments, the storage preference is a default preference. Examples of storage preferences can include: data security settings, encryption settings, data retention requirements, frequency of storage operations, such as frequency of back ups, types of data for storage operations, such as data types for back ups, types of storage operations to perform in the component group, network pathways, such as preferred network pathways to perform a storage operation, scheduling, such as a schedule of storage operations, reports, such as automatic generation of system reports regarding the group, which can include, for example the storage operations performed by the group, or other storage preference.

In some embodiments, storage device 120 is controlled by media agent 1115. For example, media agent 115 directs robotic arm 130 to obtain media 140 for export, or other storage operation. In other embodiments, storage device 120 is controlled by the storage manager 110. In this embodiment, storage manager 110 directs robotic arm 130 to obtain media 140 for export or other storage operation.

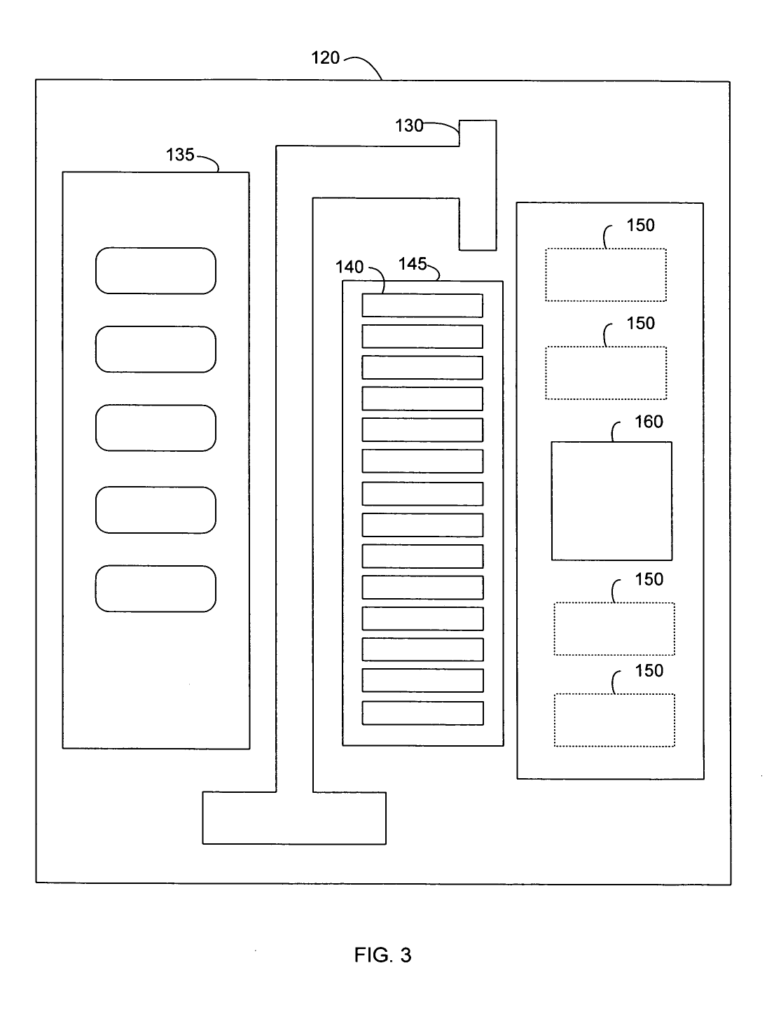

An embodiment of the storage device 120 of the present invention also includes the additional items depicted in FIG. 3, mailslot 160 and virtual mailslots 150. The mailslot 160 is generally one or more doors or exits capable of receiving, holding or storing media 140 imported into the storage device 120 and correspondingly capable of transmitting media 140 exported out of the storage device 120. The virtual mailslots 150 are generally one or more slots, or a group of slots, or other receptacle capable of receiving media 140 that will be exported out of the storage device 120, as further described herein. Preferably, the virtual mailslots 150 are relatively closer to the mailslot 160 than the slot 145 in which media 140 is located. For example, obtaining media 140 from a virtual mailslot 150 for export out of storage device 120 through mailslot 160 requires a robotic arm 130 to move a shorter distance than the distance traveled to obtain media 140 from a slot 145 or drive 135 for export through mailslot 160. The virtual mailslot 150 may be used as a temporary holding station for media 140 that is scheduled for export, or other storage operation. For example, a robotic arm 130 may be in the vicinity of a media 140 item that is scheduled for export in the near future and obtain, in advance of an export or other storage operation, the media 140 and move it to a location closer to the mailslot 160, such as the virtual mailslot 150. In preferred embodiments, media 140 is continually migrated closer to mailslot 160, for example, according to the availability of the robotic arm 130, storage policies or other parameters, to expedite exporting media 140 from the storage device 120 at the time the media 140 is needed. In existing systems, media is generally placed in storage devices without consideration. For example, the media is placed in a receptacle without referencing the receptacle location or the future storage operations scheduled for the media.

Media 140 is typically stored to a storage device 120, or to offsite storage 105, as directed by the storage manager 110. In other embodiments of the invention, the media agent 115 directs storage of media 140 to a storage device 120 or offsite storage 105. For example, the storage manager 110 or media agent 115 directs media 140 to be stored according to, for example, a storage policy. For example, a storage policy may specify that each media item be exported offsite after a certain time.

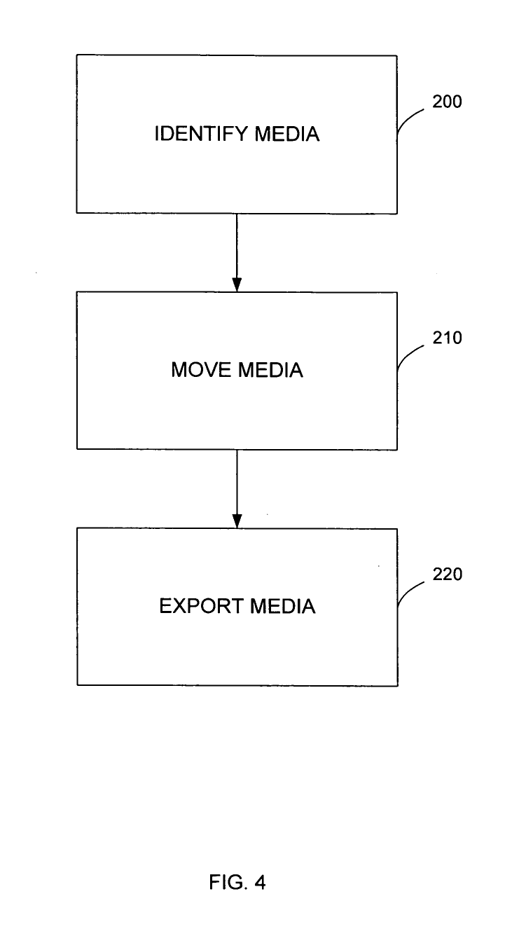

FIG. 4 depicts a high-level flow diagram of an embodiment of the invention for exporting media from storage device. The storage manager, media agent or other storage controller, initiates a media movement action. This media movement action, and other storage-related operations may be scheduled in a storage system according to a storage policy, tracking 5 policy or other retention characteristics. Media is identified, step 200, according to, for example, tracking policies, storage policies or retention characteristics, such as an export schedule. For example, in one embodiment, the storage manager identifies media in step 200, according to retention characteristics whereby the media is scheduled for export to offsite storage in the near future. In another embodiment, a media agent identifies media in step 200.

The present location of the identified media is obtained, in one embodiment of the invention, by a storage manager from the data contained in the index. In another embodiment of the invention, a media agent obtains the present location information for the identified media by consulting the index.

The identified media is moved, step 210, from its present location, which is typically a slot. The media is moved, in general, using the robotic arm. The robotic arm is directed by the storage manager in one embodiment, or alternatively, in another embodiment, by the media agent, to remove the media from its present location, such as a slot and place it in a virtual mailslot. Moving the media to the second location, such as a virtual mailslot, prior to export maximizes the efficiency of the use of a robotic arm in storage operations, in particular, in obtaining media for export operations. For example, identified media is generally obtained from a first location, such as a slot, for example, prior to the time the media is scheduled for export, such as when a robotic arm is in the vicinity of the media, and placed in a second location that is closer to the storage device exit point. The media is exported from the storage device in step 220. As discussed herein, media is exported, according to a storage policy, tracking policy or other retention characteristic, to an offsite location. Media exports are scheduled in storage policies, for example, to provide regular system and data backups to use in the event of data loss or disaster recovery.

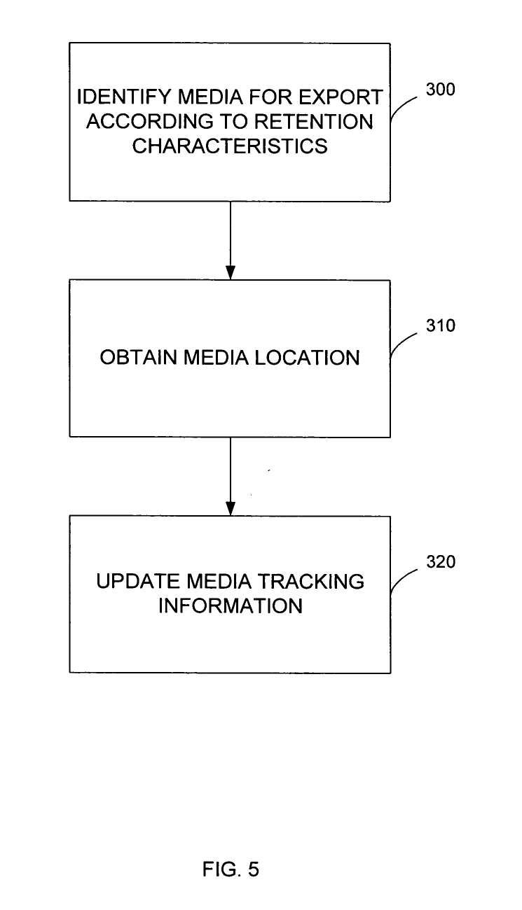

Referring to FIG. 5, which depicts a flow diagram of identifying media according to step 200 of FIG. 4, media is identified for export according to retention characteristics, step 300. The retention characteristics are based on storage policies, storage preferences, and tracking policies. Tracking policies typically include information related to the media, such as: location, due back, media status, media retention, virtual mailslot use, final destination, scheduling, back ups, alerts, reporting, or other media information. More specifically, location information in a tracking policy includes information related to the present location of media, such as a particular slot within storage device. Due back information in a tracking policy refers to media that is due to return to the system, for example, or data restore purposes. Media status information is used in tracking policies to refer to the status of the media, such as whether the media is stored locally to a storage device, or exported to offsite storage or in transit to offsite storage. Media retention information in a tracking policy provides information related to the retention characteristics for media, such as the time to store media locally to a storage device before exporting the media to offsite storage. Virtual mailslot use information is used in a tracking policy to refer to whether media is placed in virtual mailslot, for example, this information may provide an alert trigger because the media item is scheduled for export and is placed in virtual mailslot prior to export. Final destination information in a tracking policy relates to the destination for the media item, such as offsite storage. Scheduling information in a tracking policy refers to information related to the use of the media for storage operations, such as exports. Backup information in a tracking policy is set forth to create copies of data to prevent data from being lost. Alerts are used together with tracking policies to notify a user or a system of any action or movement that should alert a user or system to a storage operation, for example, an alert to media being moved into virtual mailslot indicating that the media is likely to be exported soon. Reporting information is used in tracking policies to refer to particular data items to be included in a report, for example, providing information on system storage operations and status of particular media. In general, a storage policy, storage preferences, and tracking policy are generally set to a system default policy, or customized for media by a user, for example, using a system interface further described herein.

Media identified in step 300 are typically media items scheduled for upcoming export to offsite storage locations. The location of the media identified in, step 300 is obtained, step 310. The location of the media obtained in step 310 is typically a slot in which the media is presently located. In some instances, media may also be located in a drive, or in a virtual mailslot, for example, when media is initially stored to a storage device. This can occur when media is initially stored, the storage manager, media agent, or other system component identifies the media as having an upcoming scheduled export and initially stores the media to a virtual mailslot. The tracking information related to the identified media is updated to the index, step 320. The information stored at step 320 includes for example, the location of the media, which is generally an identifier for the drive, virtual mailslot, other location, or storage device in which the media is presently located. In some embodiments, the information updated in step 320 is continually updated for each media item for every storage operation, to provide a tracking report or other tracking information for media, further described herein.

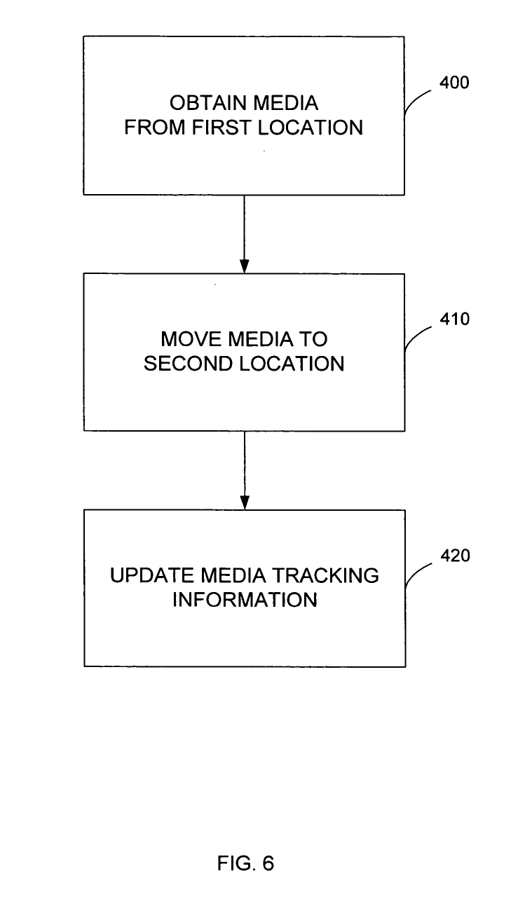

Referring to FIG. 6, which depicts a detailed flow diagram of moving media according to, step 210 of FIG. 4, the media identified in, step 300, is obtained from a first location, step 400. The first location is typically the location identified in, step 310, such as a slot, drive or virtual mailslot in which the media is located. The media is preferably obtained from the first location by the robotic arm, and moved to a second location, step 410. As described herein, the robotic arm is controlled by the storage manager, media agent or other system component. The second location is generally a virtual mailslot, slot or drive that is closer to the mailslot or storage device exit than the first location. Moving the media to the second location, such as a virtual mailslot, prior to export maximizes the efficiency of the use of the robotic arm in storage operations, in particular, in obtaining media for export operations. For example, identified media is generally obtained from a first location, such as a slot, for example, prior to the time the media is scheduled for export, such as when a robotic arm is in the vicinity of the media, and placed in a second location that is closer to the storage device exit point.

When the media is placed in the virtual mailslot, the media tracking information is updated to the index in step 420. Updating the media tracking information provides the system data to populate reports and alerts for media movements. For example, media movement to a virtual mailslot in step 410, can trigger an alert indicating that the media will be exported from the storage device.

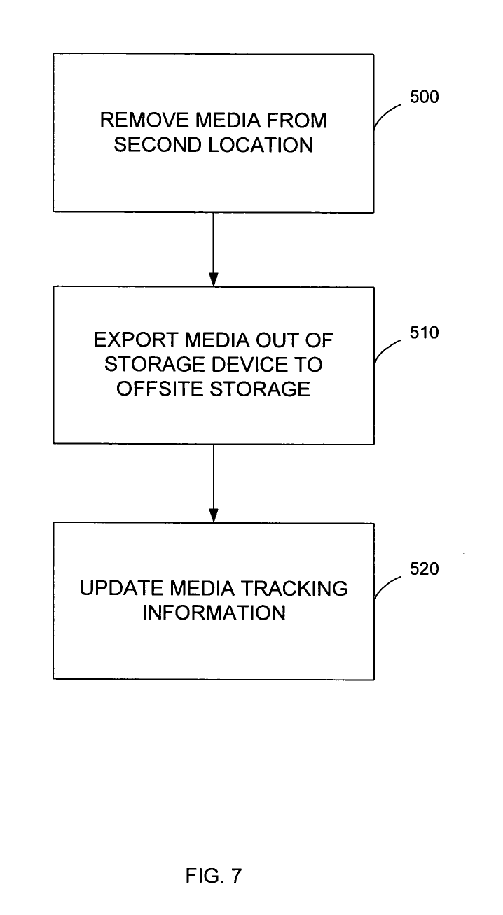

Referring to FIG. 7, which depicts a detailed flow diagram of exporting media according to, step 220 of FIG. 4, media is removed from the second location, step 500. Generally, the second location is a virtual mailslot, slot, drive or other location closer to the mailslot than the first location. Preferably, the media is obtained from the virtual mailslot by the robotic arm, and placed in a mailslot or other storage device exit point, for export out of the storage device to an offsite storage facility, step 510. As described herein, the robotic arm is controlled by the storage manager, media agent or other system component. The media tracking information related to the media export is updated, step 520 to the index.

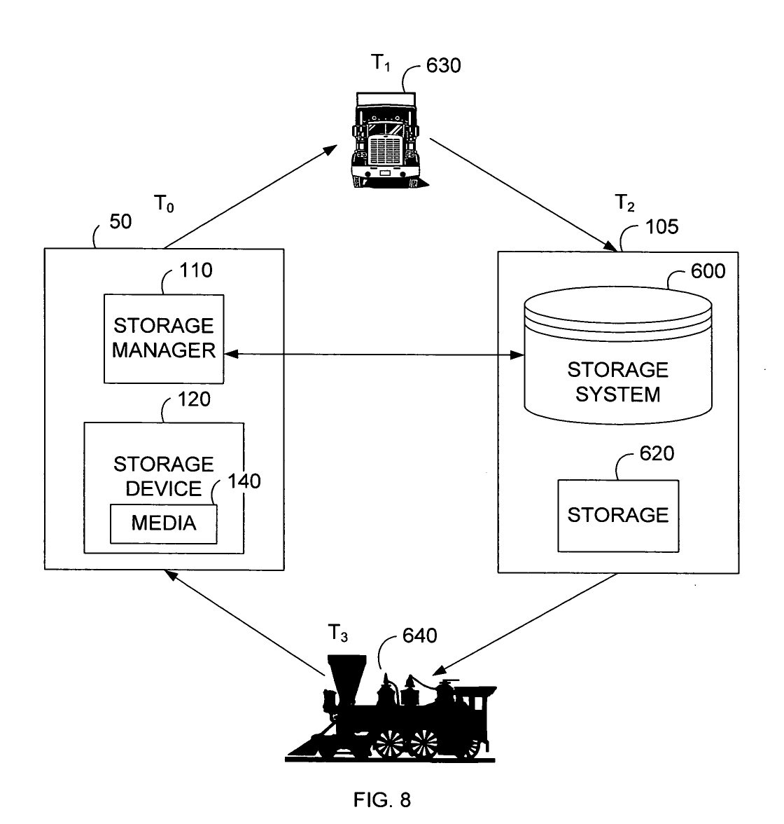

Referring to FIG. 8 which depicts a high level flow schematic of one possible embodiment of the invention, for exporting media from a storage system 50 to offsite storage 105. Storage system 50 includes at least a storage manager 110 and a storage device 120, which contains at least one media 140 item. The storage system 50 also preferably includes the components of storage system depicted in FIG. 1. The offsite storage 105 is generally a warehouse or other storage facility and includes at least a storage system 600, which may include a storage manager 110, and storage 620, which is generally any storage facility known in the art, such as silos, shelving, bins, or other storage space, and other storage system components. The storage system 50 and offsite storage 105 are connected electronically, for example via a network connection, and offline, such as via truck or train routes, or other methods.

The storage media 140 is generally exported to the offsite storage 105 via ground or other transportation. Referring to FIGS. 7 and 8, the storage media 140 is exported from the storage device 120, as further described herein at a time T₀. More specifically, in step 510 media 140 is exported out of storage device 120 to offsite storage 105. Information related to the export of the media 140 item updated to the index 125 in step 520 of FIG. 7, at time T₀. The storage media 140 is transferred 630 to the offsite storage 105, for example, using ground transportation such as a truck at a time T₁. During the transfer 630 of the storage media 140 at time T₁ to offsite storage 105, information related to the transfer 630, such as truck company and number, airway bill number, delivery service tracking number or other tracking number, or transportation updates, such as estimated time of arrival, delays, or other time related information, is provided to the storage manager 110, media agent or other system component and updated to an index. Preferably, the index also updates the information to indicate that the media 140 is in transit at time T₁.

When the media 140 arrives at offsite storage 105 at a time T₂, system 50 is notified, for example, by notifying the storage manager 110 or other system component. For example, the storage manager 110 may be notified, for example, by completion of the transfer 630, by the storage system 600, or other means. The system 50 is continually notified by the offsite storage 105 of the status of the media 140, and the media 140 status is updated to the index. For example, as the media 140 is transferred within the offsite storage 105, such as, from a receiving area to storage 620, the storage manager 110 obtains the tracking information for each media 140 item from the storage system 600. The storage system 600 is in communication with the storage manager 110, for example, by system interface, exposed APIs, or other interface technology known in the art. The tracking information obtained from the storage system 600 is preferably in the format used by storage system 600, such as, 5^{th} floor, Room 10, Bin 1, Tape 2, and is updated to the index for each media 140 item. Preferably, the index also updates the media 140 information to indicate that the media 140 item is stationary at time T₂, or at destination 105.

Obtaining the tracking information in the format used by the storage system 600 of the offsite storage facility 105 to store to the index is useful, for example, when a media item 140 is required by storage system 50. More specifically, when media 140 containing particular content is needed, the storage manager 110 or other system component refers to the index to obtain information related to the media item 140, including the offsite storage 105 location information. The storage manager 110 or other system component directs the offsite storage system 105 to return the specified media, and provides the location of the specific media 140 item, thereby obviating the need to cross reference storage data information between system 50 and offsite storage 105, to locate the specific media 140.

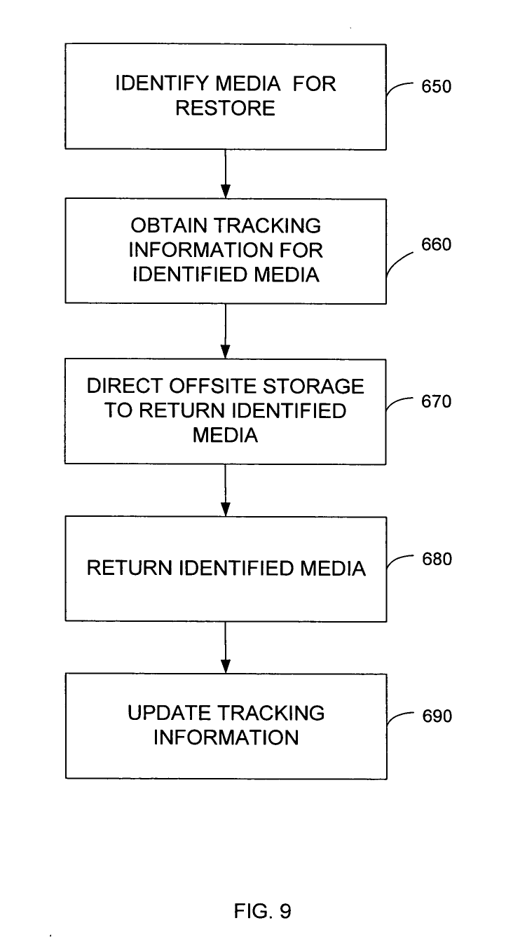

Referring to FIG. 9, which depicts a flow diagram of a restore operation of a possible embodiment of the invention, when media, located at offsite storage, is required by system, for example, for data restores or other storage operations. Media is identified for the restore operation, step 650. The media is identified in step 650 by the storage manager, media agent or other system component, by, for example, tracking policies, storage policies, storage preferences, or other directions provided by the system. The storage manager, media agent or other system component obtains the tracking information for the media item identified in step 650 by referring to data in the index, step 660. As mentioned herein, the tracking information for media stored at offsite storage is stored to the index in the format or other identifying information used by the offsite storage facility.

The storage manager, media agent or other system component initiates a restore operation, for example by directing the storage system of the offsite storage to return the identified media item, in step 670. The storage manager provides reference to the specific location of the media within the storage system of the offsite storage when directing the offsite storage facility to return the identified media. After the storage system is notified of the restore operation, the particular media is obtained from storage, exported from the offsite storage facility and returned to the storage system, step 680. The media is returned in step 680, for example, in transfer 640 of FIG. 8, via train, or other transportation, at time T₃. As described in connection with the transfer 630 at time T₁, the tracking information related to the transfer 640 at time T₃, is tracked by the storage manager, media agent, or other system component and updated to the index. Specifically, the tracking information updated to the index at T₃ can include notification from the storage system 600 that the media item is in transit, and information related to the transportation, such as train company and train number, freight bill number or other tracking number, estimate arrival time or other time-related information. When the media is returned to the storage device, the storage manager, media agent, or other system component updates the index to reflect the return of the media item, step 690. The information updated at step 690 preferably includes the successful return, the location of the media within the storage device, or other location information and tracking information.

Each of the transfers of media at times T₀, T₁, T₂ and T₃ may be repeated n times as media is exported to offsite storage 105 and restored to system 50 as required by the storage policies or other needs.

The tracking information updated to the index is generally used, as described herein, to facilitate transfers of media, in particular, to identify media based on content, identifiers or other information stored to the index, and the location of the media, both within the system or at an offsite location. For example, tracking information is used in a restore operation to locate a particular media item and direct the offsite location, providing the specific location of the media item within the offsite location, to return the media item to the system.

The tracking information can also be used as a basis for generating reports or alerts as to particular media, such as system reports on media exported to offsite storage, or alerts that media is scheduled for export. Reports include reconciliation reports, media due back reports, media information reports, or other reports detailing the status or location of media. Reconciliation reports provide a list of media pending media movement, e.g. media that has not reached its final desired location, media placed in a virtual mailslot prior to export, media that is in transit, or otherwise pending movement or transfer. Media due back reports provide a list of media that is due back to the storage device based on, for example, the last backup, restore time, or retention characteristics, such as the media identified in step 650 for a restore operation. Media information reports include generally information regarding media such as identifiers, status, movement or action identifiers, location, e.g. in a storage device, in an offsite storage facility, or in transit, e.g. at T_{1 or T}₃, association, e.g. storage policy or copy, spare, e.g. spare media providing the option to use a scratch pool and output, e.g. output format such as html, text or other format. Each of these reports and other reports provide regular information to users related to media status.

Additionally, a user may customize a report, for example, according to a policy, such as a tracking policy, or movement such as pending actions or movement history, which includes all movements, successful movements or failed movements.

Alerts are typically sent a user to alert the user to a change in the status of media. Alerts may be customized for each user, and include triggering events such as: initiation of an action, delay, completion or failure of media movement, or movement of media to a particular location, such as a virtual mailslot, retrieval of media, media reaching a destination, e.g. offsite storage, media returned to source, e.g. storage device, or media movement is rolled back. An alert may be provided in a message, pop up window, or other communication means.

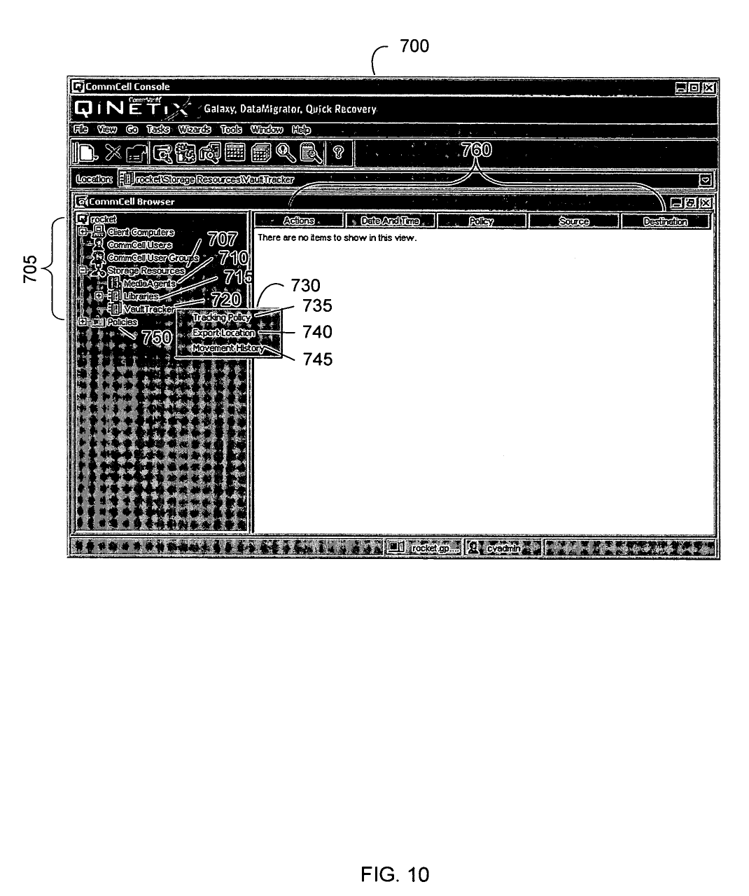

Referring to FIG. 10 which depicts a screenshot 700 of a user interface for performing storage operations and other operations according to one embodiment of the invention. The user interface provides a first window 705 for browsing the system resources, such as client computers, users, such as commcell users or commcell user groups, storage resources 707 and policies 750. Storage Resources 707 provides information using a drop down menu for Media Agents 710, Libraries 715 and Vault Tracker 720. Information, such as use or other actions or operations, for media agents is obtained by selecting Media Agents 710. Selecting Libraries 715 provides information related to storage facilities within storage devices, such as general use of slots in the storage device. Selecting Vault Tracker 720 provides the drop down menu 730 which includes Tracking Policy 735, Export Location 740, and Movement History 745. Selecting Vault Tracker 720 provides tracking information related to media, such as the tracking information updated to index, e.g. tracking policies, export location and movement history.

Vault Tracker 720 is selected to obtain information related to media and storage operations. The information displayed preferably includes the items shown in a second window 750, including actions, date and time, policy, source and destination. The heading titled Actions in the header row 760 corresponds to the storage operation or action type identifier, and refers to a particular media or group of media undergoing a particular action, such as restore, export or other action. Date and time is the date and time the action initiates or is active. Policy provides the name or other identifier for a storage policy, tracking policy or other media movement policy. Source indicates the media source, for example, the location of the media in the system. Destination is the final or export destination, such as offsite storage.

A user may select an action from the view of FIG. 10 to obtain additional information, or modify the action. Details for an action include the following: identifier for the action, date and time the state of the media changed or moved, status of the media, such as at source or system, in transit, stationary, barcode information for the media, and current location. When actions are aborted or otherwise completed, the item is removed from the Action view of FIG. 10 and stored to a history file for the media.

Still referring to FIG. 10, a user may select Tracking Policy 735, or Export Location 740 or Movement History 745 from the drop down menu 730 provided by Vault Tracker 720. Tracking Policy 735 displays the name and description of all tracking policies utilized or contemplated by the system. From the tracking policy view, a user can create, modify, add, review, run or delete a tracking policy for a particular media item. Additionally, a user can obtain the identifiers for each media subject to the same tracking policy, using for example, the tracking name. Export Location 740 includes export location, type and description, such as the location, type and description of offsite storage. From this view, a user may add, delete, or modify the location, type and description of the export location. Movement History 745 provides information including: the tracking policy, state, e.g. success or failure of an action, barcode, e.g. for media, source of the media, such as within the storage system or storage device, destination, e.g. the offsite storage, and start and end time for the action. Additionally, movement history can include movements within the storage system, storage device, including movements between drives and virtual mailslots, and transfers between the storage system and the offsite storage, for example, at times Tₙ. Additionally, movement history provides tracking location information stored to the index.

Data structures, such as database tables, are provided for tracking media items. For example, data structures are used to track the location, destination, policy, action, history, and other attributes of a particular media item.

Systems and modules described herein may comprise software, firmware, hardware, or any combination(s) of software, firmware, or hardware suitable for the purposes described herein. Software and other modules may reside on servers, workstations, personal computers, computerized tablets, PDAs, and other devices suitable for the purposes described herein.

Software and other modules may be accessible via local memory, via a network, via a browser or other application in an ASP context, or via other means suitable for the purposes described herein. Data structures described herein may comprise computer files, variables, programming arrays, programming structures, or any electronic information storage schemes or methods, or any combinations thereof, suitable for the purposes described herein. User interface elements described herein may comprise elements from graphical user interfaces, command line interfaces, and other interfaces suitable for the purposes described herein. Screenshots presented and described herein can be displayed differently as known in the art to input, access, change, manipulate, modify, alter, and work with information.

While the invention has been described and illustrated in connection with preferred embodiments, many variations and modifications as will be evident to those skilled in this art may be made without departing from the spirit and scope of the invention, and the invention is thus not to be limited to the precise details of methodology or construction set forth above as such variations and modification are intended to be included within the scope of the invention.

1. A method for performing an export operation on media stored in a storage device, the method comprising:
identifying, in advance of a scheduled export operation, at least one media item scheduled for export; and
moving, in advance of the scheduled export operation, the at least one media item from a first location within a storage device to a second location within the storage device;
wherein the second location is closer to an exit point of the storage device than the first location.

2. The method of claim 1 further comprising storing data relating to the first and second location.

3. The method of claim 1, wherein the second location is a virtual mailslot.

4. The method of claim 1, further comprising:
performing the scheduled export operation, wherein the at least one media item is moved from the second location to a third location, and wherein the third location is external to the storage device; and
receiving from a storage system associated with the third location, data relating to the third location.

5. The method of claim 4 wherein the third location is a location of the at least one media item in transit to an offsite storage location.

6. The method of claim 4 wherein the third location is within an offsite storage location.

7. The method of claim 4 further comprising generating an alert when the location of the at least one media item changes from the first location to the second location.

8. The method of claim 4 further comprising generating an alert when the location of the at least one media item changes from the second location to the third location.

9. The method of claim 4 further comprising storing the data relating to the third location.

10. The method of claim 9 further comprising generating an indication of the second and third location.

11. The method of claim 10 wherein the indication is a report including data relating to the second and third location.

12. The method of claim 9 further comprising:
receiving an instruction to restore the at least one media item;
receiving data relating to the third location of the at least one media item; and
transmitting an instruction to the storage system associated with the third location to restore the at least one media item.
